(19) United States
(12) Patent Application Publication
(10) Pub. No.: US 2024/0014063 A1
(43) Pub. Date: Jan. 11, 2024

(54) METHOD OF MANUFACTURING A SEMICONDUCTOR DEVICE

(71) Applicant: Innolux Corporation, Miao-Li County (TW)

(72) Inventors: Kai Cheng, Miao-Li County (TW); Fang-Ying Lin, Miao-Li County (TW); Tsau-Hua Hsieh, Miao-Li County (TW)

(73) Assignee: Innolux Corporation, Miao-Li County (TW)

(21) Appl. No.: 17/861,258

(22) Filed: Jul. 11, 2022

(51) Int. Cl. H01L 21/677; H01L 21/304; H01L 21/67

(52) U.S. Cl. CPC H01L 21/6779; H01L 21/3043; H01L 21/67103

(57) ABSTRACT

A method of manufacturing a semiconductor device including the following steps is provided herein. A semiconductor substrate is provided. The semiconductor substrate is transferred to a carrier. The semiconductor substrate on the carrier is diced into a plurality of semiconductor 5 components. A target substrate is provided. At least one of the semiconductor components is transferred onto the target substrate.

### BACKGROUND

### Technical Field

The disclosure is related to a method of manufacturing a semiconductor device.

### Description of Related Art

Semiconductor devices are gradually reduced in size or small devices usually require to be bonded to a target substrate for utilization. For manufacture efficiency, a mass transferring technique is provided so that a batch of semiconductor devices is able to be transferred onto the target substrate through one transferring step. Currently, the efficiency of the mass transferring technique and the transferring yield rate of the semiconductor devices are expected to be improved.

### SUMMARY

An embodiment of the disclosure directs to a method of manufacturing a semiconductor device including providing a semiconductor substrate; transferring the semiconductor substrate to a carrier; dicing the semiconductor substrate on the carrier into a plurality of semiconductor components; providing a target substrate; and transferring at least one of the semiconductor components onto the target substrate.

An embodiment of the disclosure directs to a method of manufacturing a semiconductor device including the following steps: providing a semiconductor substrate including a plurality of semiconductor units arranged with a first pitch; transferring the semiconductor substrate to a carrier; dicing the semiconductor substrate on the carrier into a plurality of semiconductor components , wherein the semiconductor components are arranged with a second pitch larger than the first pitch; providing a target substrate; and transferring at least one of the semiconductor components onto the target substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 schematically illustrates a step of a method of manufacturing a semiconductor device in accordance with some embodiments of the disclosure.

FIG. 2A and FIG. 2B schematically illustrate a step of a method of manufacturing a semiconductor device in accordance with some embodiments of the disclosure.

FIG. 3A and FIG. 3B schematically illustrate a step of a method of manufacturing a semiconductor device in accordance with some embodiments of the disclosure.

FIG. 4 schematically illustrates a side view of a step of a method of manufacturing a semiconductor device in accordance with some embodiments of the disclosure.

FIGS. 5 to 9 schematically illustrate respective steps of a transferring process of a method of manufacturing a semiconductor device in accordance with some embodiments of the disclosure.

FIG. 10 to FIG. 14 schematically illustrate respective steps of a method of manufacturing a semiconductor device in accordance with some embodiments of the disclosure.

FIG. 15 and FIG. 16 schematically illustrate several steps of a pick and place process of a method of manufacturing a semiconductor device in accordance with some embodiments of the disclosure.

FIGS. 17 and 18 schematically illustrate respective top views showing the pick and place process in accordance with some embodiments of the disclosure.

FIGS. 19 to 21 schematically illustrate several steps of a laser transfer process of a method of manufacturing a semiconductor device in accordance with some embodiments of the disclosure.

FIGS. 22 and 23 schematically illustrate respective top views showing the laser transfer process in accordance with some embodiments of the disclosure.

### DESCRIPTION OF THE EMBODIMENTS

“A structure (or layer, component, substrate, etc.) being located on/above another structure (or layer, component, substrate, etc.)” as described in the disclosure may mean that the two structures are adjacent and directly connected, or may mean that the two structures are adjacent but are not directly connected. “Not being directly connected” means that at least one intermediate structure (or intermediate layer, intermediate component, intermediate substrate, intermediate interval, etc.) is present between the two structures, where the lower surface of one structure is adjacent or directly connected to the upper surface of the intermediate structure, the upper surface of the other structure is adjacent or directly connected to the lower surface of the intermediate structure, and the intermediate structure may be composed of a single-layer or multi-layer physical structure or non-physical structure and is not specifically limited herein. In the disclosure, when one structure is disposed “on” another structure, it may mean that the one structure is “directly” on the another structure, or may mean that the one structure is “indirectly” on the another structure (i.e., at least one other structure is interposed between the one structure and the another structure).

Electrical connection or coupling as described in the disclosure may both refer to direct connection or indirect connection. In the case of direct connection, the terminal points of two components on the circuit are directly connected or are connected to each other via a conductor line segment. In the case of indirect connection, a switch, a diode, a capacitor, an inductor, a resistor, another suitable component, or a combination of the above components is present between the terminal points of two components on the circuit. However, the disclosure is not limited thereto.

In the disclosure, the length and width may be measured by an optical microscope, and the thickness may be measured according to a cross-sectional image in an electron microscope, but the disclosure is not limited thereto. In addition, there may be a certain error between any two values or directions used for comparison. If a first value is equal to a second value, it is implied that there may be an error of about 10% between the first value and the second value; if a first direction is perpendicular to a second direction, the angle between the first direction and the second direction may be 80 degrees to 100 degrees; and if the first direction is parallel to the second direction, the angle between the first direction and the second direction may be 0 degrees to 10 degrees.

In the disclosure, the embodiments to be described below may be used in combination as long as such combination does not depart from the spirit and scope of the disclosure. For example, part of the features of an embodiment may be combined with part of the features of another embodiment to form still another embodiment.

Reference will now be made in detail to the exemplary embodiments of the disclosure, examples of which are illustrated in the accompanying drawings. Whenever possible, the same reference numerals are used to represent the same or similar parts in the accompanying drawings and description.

The method of manufacturing a semiconductor device disclosed herein may include a display device, an antenna device, a sensing device or a tiled device, but the present disclosure is not limited thereto. The semiconductor device may include a bendable semiconductor device or a flexible semiconductor device. The semiconductor device may, for example, include a liquid crystal or a light emitting diode; the light emitting diode may, for example, include an organic light emitting diode (OLED), a sub-millimeter light emitting diode (mini LED), a micro light emitting diode (micro LED) or a quantum dot (QD) light emitting diode (for example, QLED or QDLED), fluorescence, phosphor or other suitable materials, and the materials may be optionally combined, but the present disclosure is not limited thereto. The tiled device may be, for example, a display tiled device or an antenna tiled device, but the present disclosure is not limited thereto.

It should be noted that the semiconductor device may be the optional combination of the above, but the present disclosure is not limited thereto. The semiconductor components may include active components or passive components, such as capacitors, resistors, inductors, diodes, transistors, integrated circuit (IC), but it is not limited. Diodes may include light emitting diode (LED), photodiode, organic light emitting diode (OLED), mini LED, micro LED, but not limited thereto.

In the description and the claims of the disclosure, the terms using the ordinal numbers, such as the first, the second or the like are used for indicating the respective elements. For example, the purpose of using the ordinal numbers is to separate one element from another element since the elements have the same term. In the disclosure, the first and the second may be used to separately indicate an electronic component before repair and another electronic component after repair. In some embodiments, the first and the second electronic component may have substantially the same property, and for example, the first and the second electronic components are LEDs.

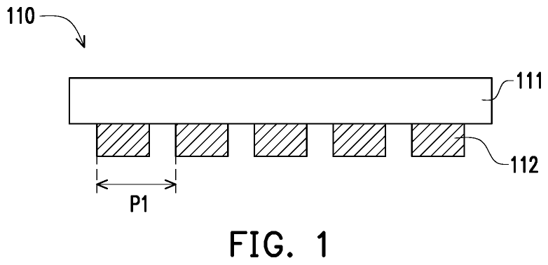

FIG. 1 schematically illustrates a step of a method of manufacturing a semiconductor device in accordance with some embodiments of the disclosure. Specifically, FIG. 1 presents the step from a side view. Referring to FIG. 1, providing a semiconductor substrate 110 including a plurality of semiconductor units 112 arranged with a first pitch P1. The first pitch P1 may be defined as a distance between the same sides of adjacent ones of the semiconductor units 112. The semiconductor substrate 110 may include a base 111 and a plurality of semiconductor units 112, the plurality of semiconductor units 112 may be formed on the base 111. In some embodiments, the semiconductor substrate 110 may include a semiconductor wafer, but the disclosure is not limited thereto. The material of the base 111 may include single crystalline silicon, poly-crystalline silicon, SiC, Si, Ge, GaAs, InP, GaN and/or other semiconductor material, but it is not limited thereto. In some embodiments, the semiconductor units 112 may be formed through the semiconductor manufacturing process which may include one or more deposition process, one or more etching process, one or more lithographic process, or a combination thereof, but it is not limited thereto.

In some embodiments, the semiconductor units 112 may be fabricated to have an individual size of sub millimeter level, micron level or the like, but it is not limited thereto. In some embodiments, the first pitch P1 may be of sub millimeter level, micron level or the like, but it is not limited thereto.

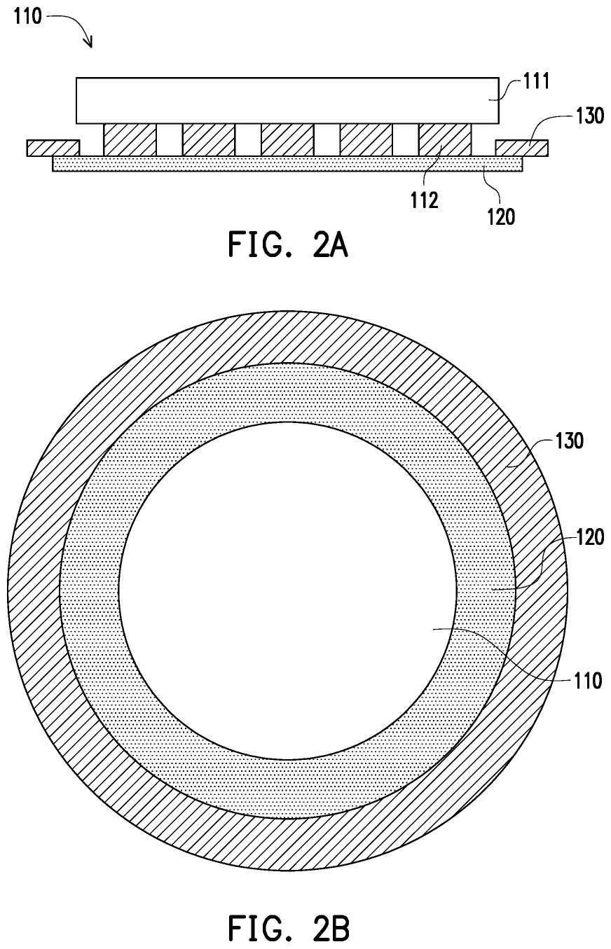

FIG. 2A and FIG. 2B schematically illustrate a step of a method of manufacturing a semiconductor device in accordance with some embodiments of the disclosure. Specifically, FIG. 2A presents the specific step from a side view and FIG. 2B presents the specific step from a top view. The step indicated by FIG. 2A and FIG. 2B includes transferring the semiconductor substrate 110 to a carrier 120 and is performed following the step indicated by FIG. 1. The carrier 120 may include a base film layer with an adhesive material formed thereon. The base film layer of the carrier 120 may include the polymer material such as PO (Polyolefin), PVC (Polyvinyl Chloride), PET (polyethylene terephthalate) or the like, but it is not limited thereto. In some embodiments, the carrier 120 may be a tape and may be stretchable and flexible. The frame 130 may be used for supporting the carrier 120 to maintain the flatness of the carrier 120.

In the embodiment, the semiconductor substrate 110 may be placed on the carrier 120 in a manner that the semiconductor units 112 face the carrier 120. The semiconductor substrate 110 including the semiconductor units 112 may be laminated and/or adhered on the carrier 120 since the carrier 120 includes an adhesive material thereon, but it is not limited thereto.

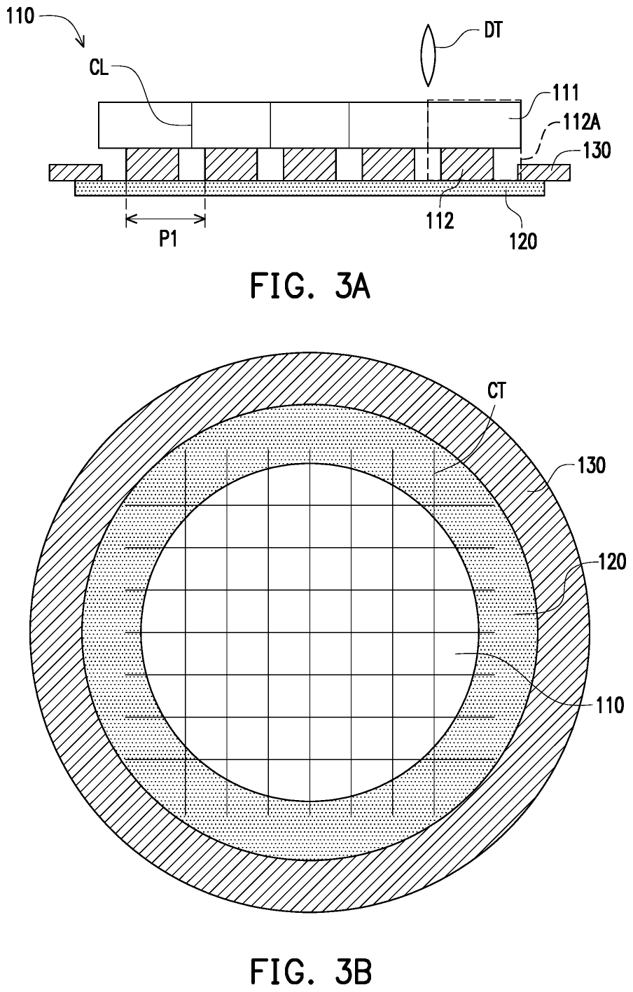

FIG. 3A and FIG. 3B schematically illustrate a step of a method of manufacturing a semiconductor device in accordance with some embodiments of the disclosure. Specifically, FIG. 3A presents the specific step from a side view and FIG. 3B presents the specific step from a top view. The step indicated by FIG. 3A and FIG. 3B includes dicing the semiconductor substrate 110 on the carrier 120 into a plurality of semiconductor components 112A. One of the plurality of semiconductor components 112A may include part of the base 111 and one of the plurality of semiconductor units 112, and it may be performed following the step indicated by FIG. 2A and FIG. 2B, but it is not limited thereto. In the embodiment, the semiconductor substrate 110 may be diced to separate the semiconductor components 112A (or the semiconductor units 112). The semiconductor substrate 110 may be diced along the cut lines CL to separate the semiconductor components 112 (or semiconductor units 112). The dicing step may be performed by carving the semiconductor substrate 110 using a dicing tool DT along the cut lines CL. In some embodiments, the dicing tool DT may be a dicing wheel, but the disclosure is not limited thereto. In some embodiments, the dicing tool DT may be a laser tool. In some embodiments, the cut lines CL may be arranged based on the initial design of the semiconductor units 112. For example, the cut lines CL may be planned based on the first pitch P1 of the semiconductor units 112. Accordingly, the semiconductor units 112 may be arranged with the first pitch P1 after the dicing step shown in FIG. 3A.

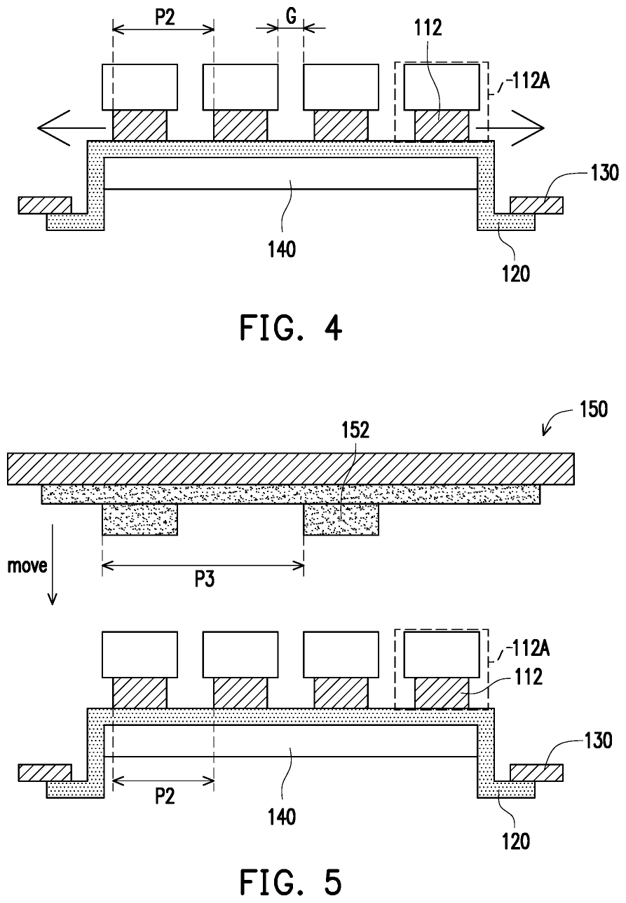

FIG. 4 schematically illustrates a side view of a step of a method of manufacturing a semiconductor device in accordance with some embodiments of the disclosure. The step indicated by FIG. 4 includes enlarging a distance between the semiconductor components 112A (or a distance between the semiconductor units 120) on the carrier 120 through expanding an area of the carrier 120. In other word, expanding an area of the carrier 120 after dicing the semiconductor substrate 110.

For example, an expanding tool 140 may be used to expand the area of the carrier 120, but it is not limited thereto. In some embodiments, the area of the carrier 120 may be expanded through stretching. The expanding tool 140 may push the carrier 120 upwardly from the bottom of the carrier 120 while the frame 130 remains at the initial level and position, but it is not limited thereto. The carrier 120 may be stretched under the pushing of the expanding tool 140 since the carrier 120 includes the stretchable material and the area of the carrier 120 is enlarged through stretching, but it is not limited thereto. As such, the distance between the semiconductor components 112A (or the distance between the semiconductor units 112) on the carrier 120 may be enlarged. For example, the semiconductor components 112A may be attached on the carrier 120, and the semiconductor components 112A may arranged with a second pitch P2 larger than the first pitch P1. The second pitch P2 may be defined as a distance between the same sides of the semiconductor units 112 of adjacent ones of the semiconductor components 112A. In addition, the semiconductor components 112A may be spaced from one another by a gap G.

The steps of FIGS. 1, 2A, 3A and 4 may serve as respective steps of a semiconductor component separation process to separate the semiconductor components 112A (or the semiconductor units 112). In some embodiments, the semiconductor component separation process may be followed by a transferring process to transfer at least one of the semiconductor components 112A to a target substrate (not shown in FIGS. 1, 2A, 3A and 4). In addition, the method of manufacturing a semiconductor device may transfer a batch of the semiconductor components 112A to improve the manufacturing efficiency.

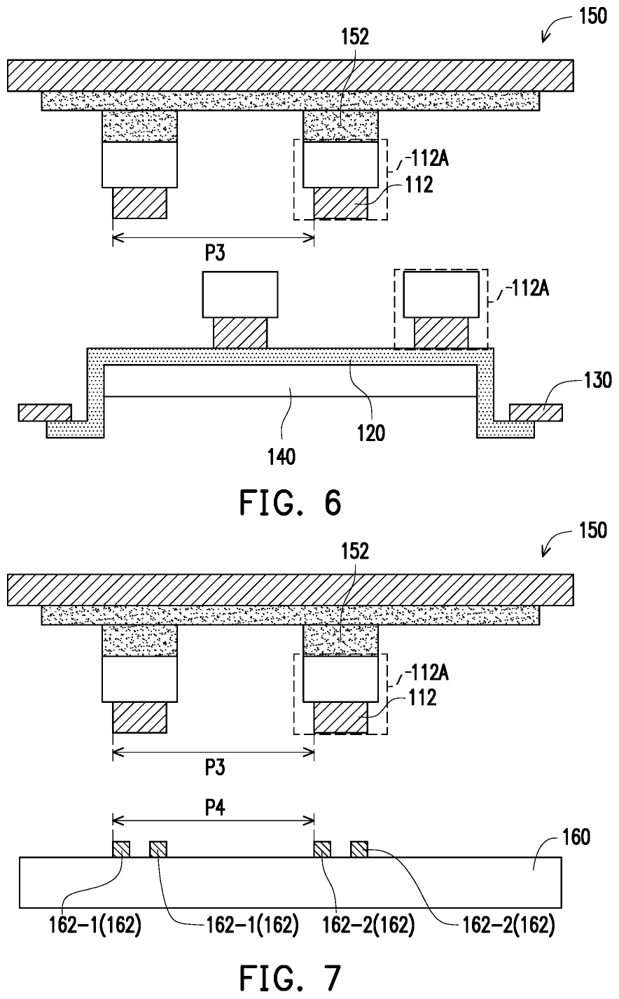

FIGS. 5 to 9 schematically illustrate respective steps of a transferring process of a method of manufacturing a semiconductor device in accordance with some embodiments of the disclosure. Specifically, FIGS. 5 to 9 present the side view of the respective steps of a pick and place process, the at least one of the semiconductor components 112A may be transferred onto the target substrate 160 through a pick and place process. In some embodiments, the steps indicated by FIGS. 5-6 may be understood as the pick stage of the pick and place process and the steps indicated by FIGS. 7-9 may be understood as the place stage of the pick and place process. In addition, the pick and place process may be performed by using a pickup head 150 shown in FIGS. 5-9. The step indicated by FIG. 5 includes moving the pickup head 150 over the carrier 120 carrying the semiconductor components 112A including the semiconductor units 112, the semiconductor components 112A may be arranged with the second pitch P2. The pickup head 150 may include a plurality of pickup sites 152 formed thereon. The material of the pickup sites 152 may include PDMS, organic material, photo resin, adhesive material, polyimide, or the like, but it is not limited thereto. In some embodiments, the pickup sites 152 of the pickup head 150 may be arranged with a third pitch P3 different from the second pitch P2 of the semiconductor components 120. In some embodiments, the third pitch P3 may be greater than the second pitch P2, but it is not limited thereto. For example, the third pitch P3 may be an integer multiple of the second pitch P2, but it is not limited thereto. In some alternative embodiments, the third pitch P3 may be identical to the second pitch P2, but it is not limited thereto.

In the step indicated by FIG. 5, the pickup head 150 may be oriented that the pickup sites 152 face the semiconductor components 112A carried by the carrier 120. Subsequently, the pickup head 150 may be moved downwardly until the pickup sites 152 in contact with the corresponding semiconductor components 112A. Then, the step indicated by FIG. 6 is performed to pick up the semiconductor components 112A from the carrier 120. The attaching strength between the pickup sites 152 and the semiconductor components 112A may be greater than the attaching strength between the carrier 120 and the semiconductor components 112A. Therefore, the pickup head 150 picks up the corresponding semiconductor components 112A from the carrier 120 by contacting the pickup sites 152 to the corresponding semiconductor components 112A followed by moving away from the carrier 120, and thus the semiconductor components 112A picked by the transfer sites 152 are arranged with the third pitch P3. The third pitch P3 may be greater than the second pitch P2 of the semiconductor components 112A shown in FIG. 5, and a portion of the semiconductor components 112A may be picked up while the other portion of the semiconductor components 112A remains on the carrier 120. In some embodiments, the steps of FIGS. 5 and 6 may be known as the pick stage in the pick and place process and the pick stage in the embodiment may selectively pick up the semiconductor components 112A corresponding to the pickup sites 152 so as to achieve the effect of a selective pickup.

Thereafter, the step indicated by FIG. 7 including providing a target substrate 160 is performed. Specifically, the target substrate 160 may include the bonding structures 162 formed thereon. In some embodiments, each of the bonding structures 162 may include a group of bonding pads. For example, one bonding structure 162 includes a group of bonding pads 162-1, and another bonding structure 162 includes a group of bonding pads 162-2, but it is not limited thereto. The bonding structures 162 is disposed for bonding to respective one of the semiconductor components 112A. The step indicated in FIG. 7 also includes moving the pickup head 150 over the target substrate 160. The pickup head 150 may be oriented that the pickup sites 152 carrying the semiconductor components 112A may face the bonding structures 162 on the target substrate 160. In some embodiments, the bonding structures 162 may be arranged with a fourth pitch P4, the fourth pitch P4 may be corresponding to the third pitch P3 of the semiconductor components 112A carried by the pickup head 150. For example, the fourth pitch P4 may be identical to the third pitch P3, the semiconductor components 112A carried by the pickup head 150 may be positioned aligned with the bonding structures 162, but it is not limited thereto. In some alternative embodiments, the third pitch P3 may be an integer multiple of the fourth pitch P4 so that the semiconductor components 112A carried by the pickup head 150 may be positioned aligned with a portion of the bonding structures 162, but it is not limited thereto. In some embodiments, the pitch P3 and the pitch P4 may be planned that the semiconductor components 112A carried by the pickup head 150 are arranged corresponding to the arrangement of a selected portion of the bonding structures 162. In other words, the arrangement of the pickup sites 152 of the pickup head 150 may be planned based on the arrangement of the bonding structures 162 of the target substrate 160.

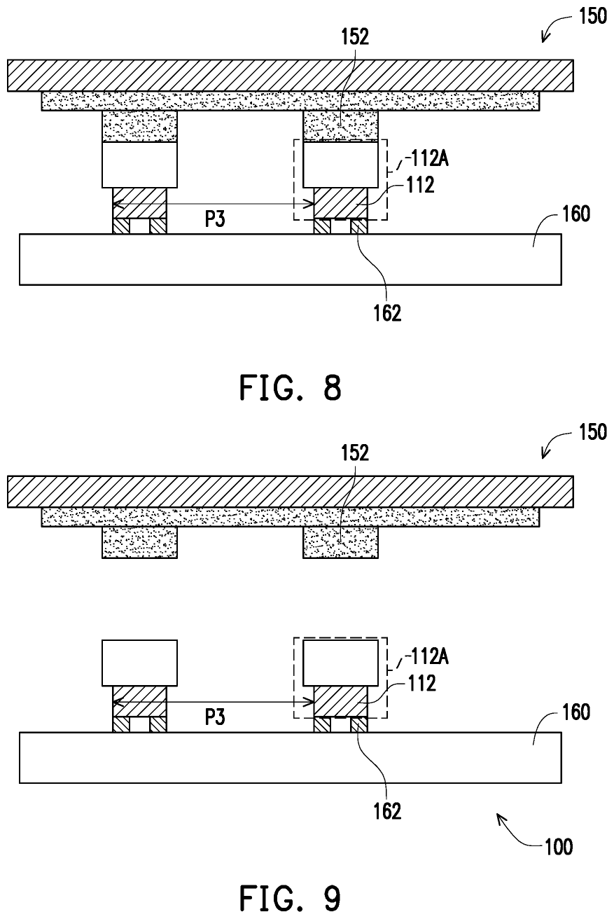

Thereafter, the pickup head 150 is moved toward the target substrate 160 to allow the semiconductor components 112A in contact with the bonding structures 162 of the target substrate 160 as indicated by FIG. 8. The semiconductor components 112A may be placed on the target substrate 160. In some embodiments, the semiconductor components 112A may be bonded to the bonding structures 162 in the step of FIG. 8.

Then, the pickup head 150 is removed from the semiconductor components 112A as the step indicated by FIG. 9 to achieve the semiconductor device 100. In some embodiments, the attaching strength between the pickup sites 152 and the semiconductor components 112A may be less than the boning strength between the bonding structures 162 and the semiconductor components 112A, the pickup head 150 may be moved from the semiconductor components 112A after the bonding between the bonding structures 162 and the semiconductor components 112A is achieved. In some embodiments, a step of reducing the attaching strength between the pickup sites 152 and the semiconductor components 112A may be selectively performed after bonding the semiconductor components 112A to the bonding structures 162 so as to easily move away the pickup head 150 from the semiconductor components 112A. The step of reducing the attaching strength between the pickup sites 152 and the semiconductor components 112A may include a laser irradiation on the pickup sites 152, but it is not limited thereto.

The semiconductor device 100 includes the target substrate 160 and the semiconductor components 112A bonded to the bonding structure 162 of the target substrate 160. The semiconductor components 112A may be transferred and bonded onto the target substrate 160 in a batch through the steps depicted in FIG. 1, FIG. 2A, FIG. 2B, FIG. 3A, FIG. 3B and FIGS. 4 to 9, but it is not limited thereto. In some embodiments, the semiconductor components 112A may be transferred onto various regions of the target substrate 160 through multiple cycles of the pick and place process indicate by FIGS. 5 to 9. In the embodiment, the semiconductor components 112A bonded to the target substrate 160 may be arranged with the third pitch P3 that is related to the pitch design of the pickup sites 152 of the pickup head 150. However, in some embodiments, the semiconductor components 112A transferred on the target substrate 160 through one cycle of the pick and place process may be arranged with a pitch different from the pitch design of the pickup sites 152 of the pickup head 150, but multiple cycles of the pick and place process may be performed to transfer the semiconductor components 112A on all of the bonding structures 162, but it is not limited thereto.

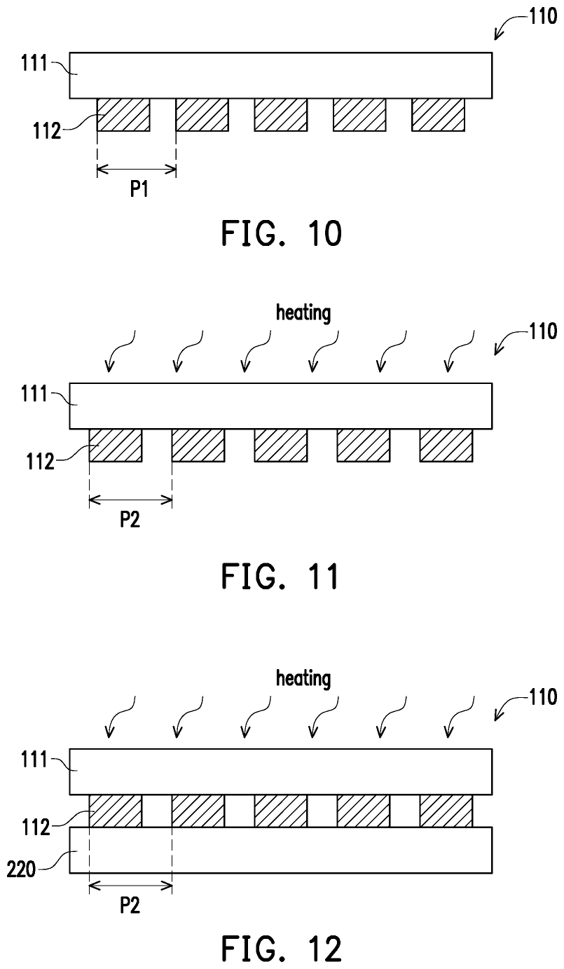

FIG. 10 to FIG. 14 schematically illustrate respective steps of a method of manufacturing a semiconductor device in accordance with some embodiments of the disclosure. Specifically, the steps of FIG. 10 to FIG. 14 may provide a semiconductor component separation process to separate the semiconductor components and may be an alternative of the process described in FIGS. 1, 2A, 3A and 4. In FIG. 10, the step of providing a semiconductor substrate 110 similar to that described in FIG. 1 is shown. The semiconductor units 112 of the semiconductor components 112A may be initially arranged with the first pitch P1. Specifically, the descriptions of FIG. 1 are applicable in the present embodiment and are not reiterated.

In FIG. 11, a step of expanding an area of the semiconductor substrate 110 may be performed. In some embodiments, the area of the semiconductor substrate 110 may be enlarged through heating before transferring the semiconductor substrate 110 to the carrier 220, but it is not limited thereto. Due to the thermal expansion of the semiconductor substrate 110, the spacing between the semiconductor components 112 may be enlarged so that the semiconductor components 112 are arranged in a second pitch P2 that is larger than the first pitch P1, but it is not limited thereto. In some embodiments, the spacing between the semiconductor components 112A may be adjusted according to design, and for example, the spacing between the semiconductor components 112A may be compressed or enlarged. Then, a step of transferring the semiconductor substrate 110 to a carrier 220 as shown in FIG. 12 is performed. The semiconductor substrate 110 may be laminated the carrier 220, wherein the semiconductor substrate 110 may be laminated the carrier 220 in a manner that the semiconductor components 112 facing the carrier 220. In some embodiments, the carrier 220 may include a surface material (not shown) adjacent to the semiconductor components 112A thereon, the semiconductor components 112A may be attached to the carrier 220 through the surface material, but it is not limited thereto. The surface material may include an adhesive material, an organic material, or a photo resin, or other suitable material, but it is not limited thereto.

The semiconductor substrate 110 may be heated until being transferred to the carrier 220, but it is not limited thereto. The semiconductor substrate 110 in the heated state may keep the semiconductor components 112A arranged with the second pitch P2, so that the semiconductor components 112A attached onto the carrier 220 may remain arranged with the second pitch P2, but it is not limited thereto. Thereafter, the heating of the semiconductor substrate 110 may stop after the semiconductor substrate 110 laminating to the carrier 220 as shown in FIG, 13. The carrier 220 may include a rigid carrier, the carrier 22 hardly stretchable so that under the support and carry of the carrier 220, the semiconductor components 112A may remain arranged with the second pitch P2 after the heating stops, but it is not limited thereto.

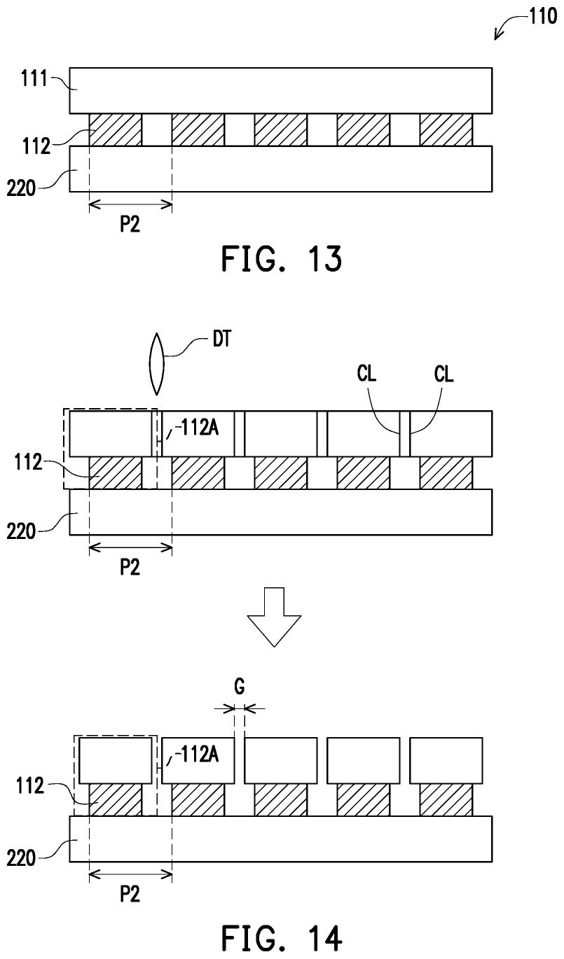

In FIG. 14, a step of dicing the semiconductor substrate 110 on the carrier 120 is performed after the step of FIG. 13 to separate the semiconductor components 112A (or the semiconductor units 112A). In some embodiments, the semiconductor substrate 110 is diced to separate the semiconductor components 112A including a part of the base 111 and one of the plurality of semiconductor units 112. The dicing step may be performed by carving the semiconductor substrate 110 using a dicing tool DT along the cut lines CL, but it is not limited thereto. In the embodiment, the cut lines CL may be planned between two adjacent semiconductor units 112, the semiconductor components 112A may be spaced from one another by a gap G, but it is not limited thereto. In addition, after dicing the semiconductor substrate 110, the semiconductor components 112A carried by the carrier 220 may be arranged with the second pitch P2, but it is not limited thereto.

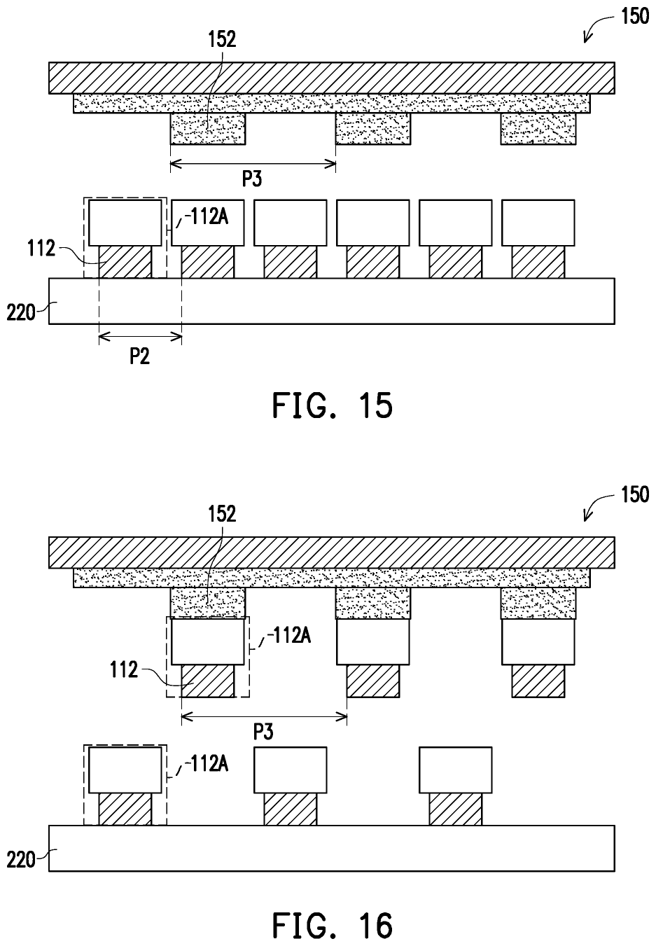

FIG. 15 and FIG. 16 schematically illustrates several steps of a pick and place process of a method of manufacturing a semiconductor device in accordance with some embodiments of the disclosure. FIG. 15 and FIG. 16 present the side view of the pick stage of the pick and place process and the steps of FIGS. 7 to 9 related to the place stage of the pick and place process may be performed after the step of FIG. 16 to fabricate the semiconductor device 100 shown in FIG. 9.

In FIG. 15, the pickup head 150 as described in the previous embodiment is provided and is moved over the carrier 220 carrying the semiconductor components 112A including the semiconductor units 112, the semiconductor units 112 are arranged with the second pitch P2. Similar to the previous embodiment, the pickup head 150 may include a plurality of pickup sites 152 formed thereon and the pickup sites 152 of the pickup head 150 may be arranged with a third pitch P3 related to the second pitch P2 of the semiconductor units 120, but it is not limited thereto. In the embodiment, the third pitch P3 may be greater than the second pitch P2, but it is not limited thereto. For example, the third pitch P3 may be an integer multiple of the second pitch P2, but it is not limited thereto. In some alternative embodiments, the third pitch P3 may be identical to the second pitch P2. In some embodiments, the second pitch P2 and the third pitch P3 may be planned that each of the pickup sites 152 is able to be in contact with one of the semiconductor components 112A.

The pickup head 150 may be oriented that the pickup sites 152 face the semiconductor components 112A carried by the carrier 120 and move toward the carrier 220 until the pickup sites in contact with the corresponding semiconductor components 112A. Accordingly, at least one of the semiconductor components 112A may be attached to the pickup sites 152. In some embodiments, the attaching strength between the pickup sites 152 and the semiconductor components 112A may be greater than the attaching strength between the carrier 120 and the semiconductor components 112A, but it is not limited thereto. Therefore, the semiconductor components 112A in contact with the pickup sites 152 may be picked up by the pickup head 150 from the carrier 120 by moving the pickup head 150 away from the carrier 220 as shown in FIG.

16. The semiconductor components 112 carried by the pickup head 150 may be arranged in the third pitch P3. Thereafter, the steps of FIGS. 7 to 9 presenting the place stage of the pick and place process are performed after the step of FIG. 16 to finish the semiconductor device 100 shown in FIG. 9. Therefore, the related description is not reiterated.

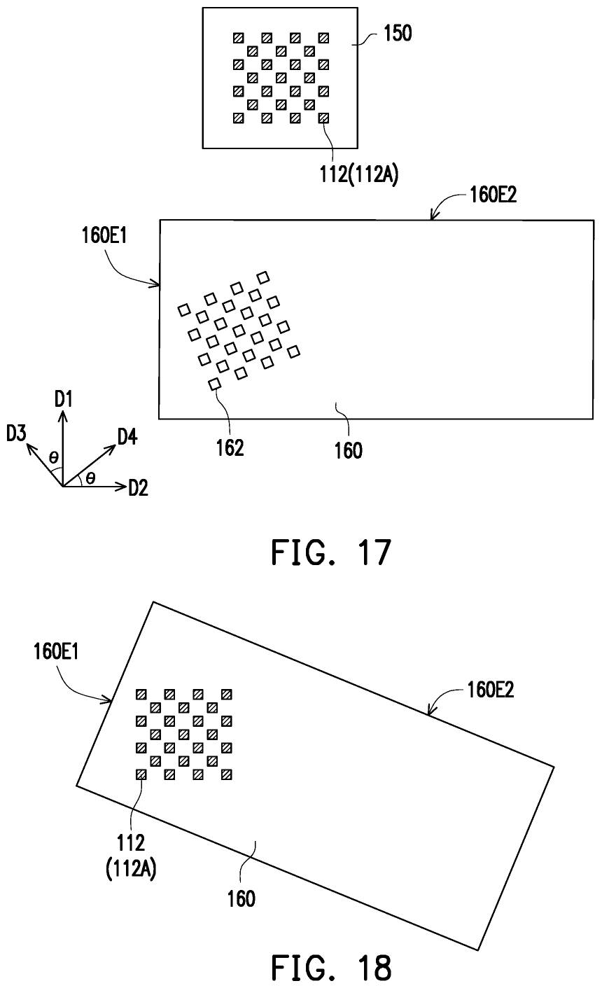

FIGS. 17 and 18 schematically illustrate respective top views showing the pick and place process in accordance with some embodiments of the disclosure. In FIG. 17, the target substrate 160 may include the bonding structures 162 formed thereon, and the pickup head 150 carrying the semiconductor components 112A is positioned over the target substrate 160. The top view of FIG. 17 may be served as an embodiment of the step indicated by FIG. 7.

In the embodiment, the target substrate 160 may have a rectangular shape, one edge 160E1 of the target substrate 160 may extend along the direction D1, another edge 160E2 of the target substrate 160 may extend along the direction D2 perpendicular to the direction D1, but it is not limited thereto, the target substrate 160 may have other suitable shape. In the embodiment, the bonding structures 162 on the target substrate 160 may be arranged in an array in the direction D3 and the direction D4 perpendicular to the direction D3, but it is not limited thereto. The direction D3 and the direction D1 may be included by an angle θ, but it is not limited thereto. Similarly, the direction D4 and the direction D2 may be included by the same angle θ, but it is not limited thereto. In other words, the array of the bonding structures 162 may be oriented obliquely to the geometric shape of the target substrate 160, but it is not limited thereto. In addition, the semiconductor components 112A may be arranged on the pickup head 150 in an array corresponding to the array of the target substrate 160. In addition, the array of the semiconductor components 112A on the pickup head 150 may be oriented parallel to the geometric shape of the pickup head 150, but it is not limited thereto.

In some embodiments, as shown in FIG. 17, the pick and place process may include a step of aligning the semiconductor components 112A with the bonding structures 162. For example, one of the target substrate 160 and the pickup head 150 may be rotated by the angle θ to align the array of the semiconductor components 112A with the array of the bonding structures 162. In some embodiments, at least one of the semiconductor components 112A may be transferred onto the target substrate 160 by picking up the at least one of the semiconductor components 112A using a pickup head, and rotating the pickup head 150 by the angle θ with respect to the target substrate 160, but it is not limited thereto. In alternative embodiments, at least one of the semiconductor components 112A may be transferred onto the target substrate 160 by picking up the at least one of the semiconductor components 112A using a pickup head, and rotating the target substrate 160 by the angle θ with respect to the pickup head 150. After the aligning step, the pickup head 150 is moved toward the target substrate 160 and the semiconductor components 112A are transferred to the bonding structures 162 on the target substrate 160 as shown in FIG. 18. The step of transferring the semiconductor components 112A from the pickup head 150 to the target substrate 160 may refer to the descriptions of FIGS. 7 to 9.

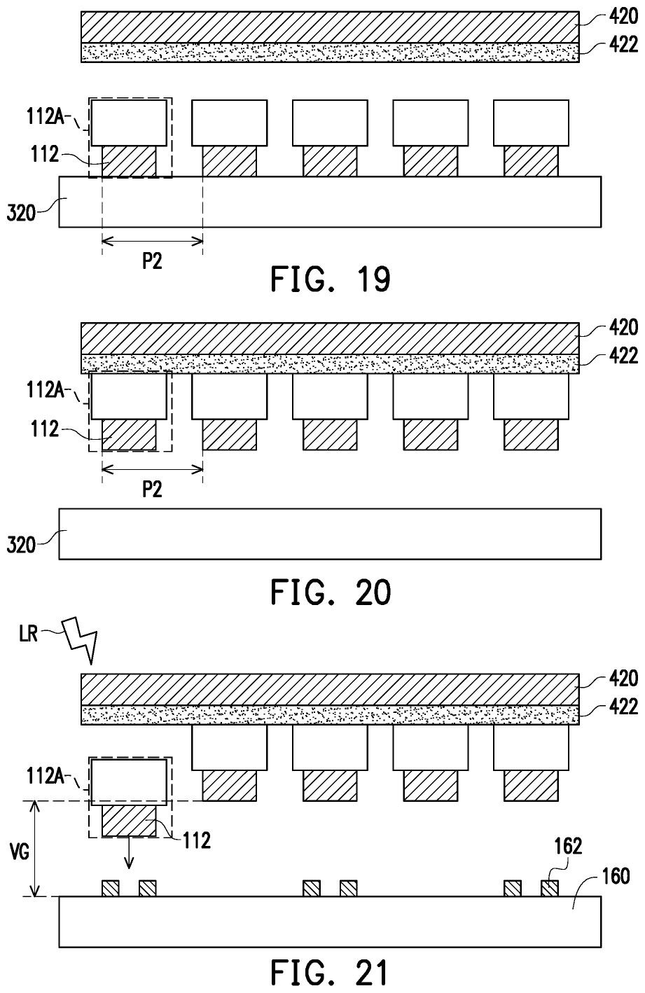

FIGS. 19 to 21 schematically illustrate several steps of a laser transfer process of a method of manufacturing a semiconductor device in accordance with some embodiments of the disclosure. FIGS. 19 to 21 present the side view of the laser transfer process and may be served as an alternative of the pick and place process described in the previous embodiments. In FIG. 19, the semiconductor components 112A may be carried by a carrier 320 which may be implemented by the carrier 120 or the carrier 220 described in the previous embodiments. In other words, the step of FIG. 19 may be performed after the step of FIG. 4 or the step of FIG. 14. In the embodiment, the semiconductor components 112A may be formed by the steps described in FIGS. 1 to 4 or the steps described in FIGS. 10 to 14, but it is not limited thereto, and thus the semiconductor components 112A may be arranged with the second pitch P2 on the carrier 320. Another carrier 420 may be provided and positioned over the carrier 320. A sacrificial layer 422 may be formed on the carrier 420, and the carrier 420 is positioned over the carrier 320 in a manner that the sacrificial layer 422 facing the semiconductor components 112A carried by the carrier 320. In other word, the sacrificial layer 422 may be disposed between the carrier 320 and the carrier 420.

In some embodiments, the sacrificial layer 422 may include an organic material, a polyimide based material or other material, but it is not limited thereto. The sacrificial layer 422 may adhere the semiconductor components 112A to the carrier 420. The adhesion between the semiconductor components 112A and the sacrificial layer 422 may be greater than the attaching strength between the semiconductor components 112A and the carrier 320, but it is not limited thereto. Therefore, the semiconductor components 112A are transferred to the carrier 420 from the carrier 320 as shown in FIG. 20. The sacrificial layer 422 on the carrier 420 may be formed continuously on the surface of the carrier 420, and the semiconductor components 112A positioned within the area of the sacrificial layer 422 may be adhered by the sacrificial layer 422, but it is not limited thereto. In the embodiment, the semiconductor components 112A transferred on the carrier 420 remain arranged with the second pitch P2.

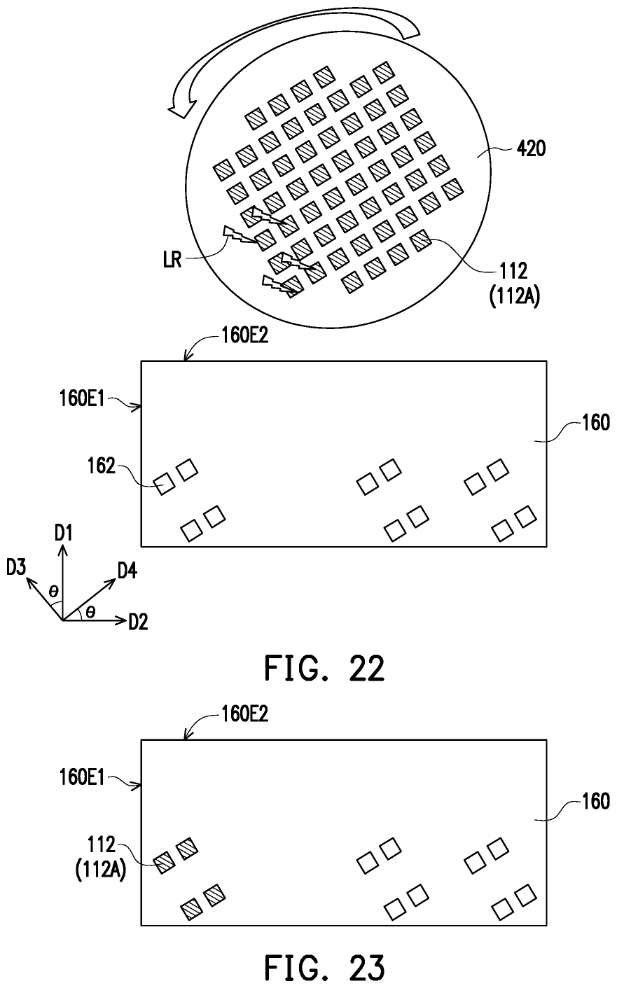

Thereafter, as shown in FIG. 21, the step of transferring the semiconductor components 112 to the target substrate 160 from the carrier 420 is performed. In the embodiment, the semiconductor components 112A may be transferred to the target substrate 160 from the carrier 420 by irradiating a laser LR to the sacrificial layer 422 on the carrier 420. In other word, the at least one of the semiconductor components 112A is transferred onto the target substrate 160 through a laser transfer process. Similar to the previous embodiments, the target substrate 160 may include the bonding structures 162 formed thereon. The carrier 420 is positioned over the target substrate 160 in a manner that at least one of the semiconductor components 112A is aligned with the bonding structures 162. In addition, the carrier 420 may be positioned at a level that the semiconductor components 112 may be spaced from the target substrate 160 by a vertical gap VG which may be from 0 μm to 1000 μm, but it is not limited thereto. The laser LR irradiates the sacrificial layer 422 at the position of the semiconductor component 112A aligned with the corresponding bonding structure 162 and the irradiated portion of the sacrificial layer 422 may be decomposed, or damaged to break the adhesion to the semiconductor component 112A. Therefore, the semiconductor component 112A corresponding to the irradiated portion of the sacrificial layer 422 may be released from the carrier 420 and transferred to the target substrate 160. In some embodiments, the laser LR may irradiate the sacrificial layer 422 at a plurality of positions at once, several semiconductor components 112A may be transferred to the target substrate 160 from the carrier 420 in a bath, but it is not limited thereto. Therefore, the laser transfer process may achieve the effect of mass transferring. In addition, the irradiation position of the laser LR may be adjusted to transfer the selected semiconductor component 112A to the corresponding bonding structure 162 and thus the laser transfer process may further achieve the effect of selective transfer. After transferring the semiconductor components 112A onto the target substrate 160, the semiconductor components 112A may be bonded to the target substrate 160 to obtain the semiconductor device 100.

FIGS. 22 and 23 schematically illustrate respective top views showing the laser transfer process in accordance with some embodiments of the disclosure. In FIG. 22, the target substrate 160 may include the bonding structures 162 formed thereon and the carrier 420 carrying the semiconductors components 112A is positioned over the target substrate 160. The top view of FIG. 22 may be served an embodiment of the step indicated by FIG. 21, but the disclosure is not limited thereto. In the embodiment, the target substrate 160 may have a rectangular shape, one edge 160E1 of the target substrate 160 may extend along the direction D1, another edge 160E2 of the target substrate 160 may extend along the direction D2 perpendicular to the direction D1, but it is not limited thereto, the target substrate 160 may have other suitable shape. The bonding structures 162 on the target substrate 160 may be arranged in an array in the direction D3 and the direction D4 perpendicular to the direction D3, but it is not limited thereto. Similarly, the direction D4 and the direction D2 may be included by the same angle 0, but it is not limited thereto. In other words, the array of the bonding structures 162 is oriented obliquely to the geometric shape of the target substrate 160.

As shown in FIG. 22, the laser transfer process may include a step of aligning the semiconductor components 112A (or the semiconductor units 112) with the bonding structures 162. For example, one of the target substrate 160 and the carrier 420 may be rotated by the angle to align the orientation of the semiconductor components 112A to be transferred with the corresponding bonding structures 162. After aligning the semiconductor components 112A to be transferred with the corresponding one bonding structures 162, the laser LR may be irradiated on the carrier 420 to release the semiconductor components 112A from the carrier 420 and transfer the semiconductor components 112A to the target substrate 160 as shown in FIG. 23. In some embodiments, the laser LR may irradiate at several positions where the corresponding semiconductor components 112A are aligned with the bonding structures 162 to release several corresponding semiconductor components 112A while other semiconductor components 112A remain on the carrier 420, but it is not limited thereto. Accordingly, the laser transfer process may provide an effect of selective transferring and also an effect of mass transferring.

Based on the embodiments described in above, the method of manufacturing a semiconductor device 100 is configured for transferring a plurality of semiconductor components 112 onto the target substrate 160. The method of manufacturing the semiconductor device 100 may include a semiconductor component separation process and a subsequent transferring process. As shown in FIGS. 1 to 4 and FIGS. 10 to 14 which represent various embodiments of the semiconductor component separation process, the semiconductor units 112 of the semiconductor substrate 110 may be initially arranged with the first pitch P1, and then separated from one another with the arrangement of the enlarged pitch (such as second pitch P2), but it is not limited thereto. Therefore, the subsequent transferring process such as the pick and place process of FIGS. 6 to 9 or the laser transfer process of FIGS. 19 to 21 may capture and transfer the individual semiconductor components 112A without difficulty, but it is not limited thereto. In some embodiments, in the pick and place process of FIGS. 5 to 9, the semiconductor components 112A may be selectively picked up based on the pitch design of the pickup sites 152 of the pickup head 150. Accordingly, a selective transferring may be achieved. In the laser transfer process of FIGS. 19 to 21, the semiconductor components 112A may be arranged with the second pitch P2 and separated from one another on the carrier 420 so that the laser LR may correctly irradiate on the position based on the semiconductor unit 112 to be transferred. Therefore, a selective transferring may be also achieved. In some embodiments, after the semiconductor component separation process, the semiconductor components are able to be transfer to the target substrate 160 in batch so as to accomplish a mass transferring process which saves the manufacturing time and is helpful for small sized semiconductor components.

In light of the above, the method of manufacturing a semiconductor device in the disclosure involve good efficiency, achieves the effect of selective transferring and is helpful for small sized semiconductor components.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of manufacturing a semiconductor device, comprising:
providing a semiconductor substrate;
transferring the semiconductor substrate to a carrier;
dicing the semiconductor substrate on the carrier into a plurality of semiconductor components;
providing a target substrate; and
transferring at least one of the semiconductor components onto the target substrate.

2. The method of manufacturing the semiconductor device of claim 1, further enlarging a distance between the semiconductor components on the carrier through expanding an area of the carrier.

3. The method of manufacturing the semiconductor device of claim 2, wherein the area of the carrier is expanded through stretching.

4. The method of manufacturing the semiconductor device of claim 1, further expanding an area of the semiconductor substrate before transferring the semiconductor substrate to the carrier.

5. The method of manufacturing the semiconductor device of claim 4, wherein the area of the semiconductor substrate is expanded through heating.

6. The method of manufacturing the semiconductor device of claim 5, wherein the semiconductor substrate is heated until being transferred to the carrier.

7. The method of manufacturing the semiconductor device of claim 1, wherein the at least one of the semiconductor components is transferred onto the target substrate through a pick and place process.

8. The method of manufacturing the semiconductor device of claim 1, wherein the at least one of the semiconductor components is transferred onto the target substrate through a laser transfer process.

9. The method of manufacturing the semiconductor device of claim 1, wherein the at least one of the semiconductor components is transferred onto the target substrate by
picking up the at least one of the semiconductor components using a pickup head; and
rotating the pickup head by an angle with respect to the target substrate.

10. The method of manufacturing the semiconductor device of claim 1, wherein the at least one of the semiconductor components is transferred onto the target substrate by
picking up the at least one of the semiconductor components using a pickup head; and
rotating the target substrate by an angle with respect to the pickup head.

11. A method of manufacturing a semiconductor device, comprising:
providing a semiconductor substrate including a plurality of semiconductor units, arranged with a first pitch;
transferring the semiconductor substrate to a carrier;
dicing the semiconductor substrate on the carrier into a plurality of semiconductor components, wherein the semiconductor components are arranged with a second pitch larger than the first pitch;
providing a target substrate; and
transferring at least one of the semiconductor components onto the target substrate.

12. The method of manufacturing the semiconductor device of claim 11, further expanding an area of the carrier after dicing the semiconductor substrate.

13. The method of manufacturing the semiconductor device of claim 12, wherein the area of the carrier is expanded through stretching.

14. The method of manufacturing the semiconductor device of claim 11, further expanding an area of the semiconductor substrate before transferring the semiconductor substrate to the carrier.

15. The method of manufacturing the semiconductor device of claim 14, wherein the area of the semiconductor substrate is expanded through heating.

16. The method of manufacturing the semiconductor device of claim 15, wherein the semiconductor substrate is heated until being transferred to the carrier.

17. The method of manufacturing the semiconductor device of claim 11, wherein the at least one of the semiconductor components is transferred onto the target substrate through a pick and place process.

18. The method of manufacturing the semiconductor device of claim 11, wherein the at least one of the semiconductor components is transferred onto the target substrate through a laser transfer process.

19. The method of manufacturing the semiconductor device of claim 11, wherein the at least one of the semiconductor components is transferred onto the target substrate by
picking up the at least one of the semiconductor components using a pickup head; and
rotating the pickup head by an angle with respect to the target substrate.

20. The method of manufacturing the semiconductor device of claim 11, wherein the at least one of the semiconductor components is transferred onto the target substrate by
picking up the at least one of the semiconductor components using a pickup head; and
rotating the target substrate by an angle with respect to the pickup head.
